(19) United States
(12) Patent Application Publication
(10) Pub. No.: US 2012/0020166 A1
(43) Pub. Date: Jan. 26, 2012

(54) NONVOLATILE SEMICONDUCTOR STORAGE DEVICE

(75) Inventor: Hiroyuki ISHII, Kamakura-Shi (JP)

(73) Assignee: KABUSHIKI KAISHA TOSHIBA, Tokyo (JP)

(21) Appl. No.: 13/029,452

(22) Filed: Feb. 17, 2011

(30) Foreign Application Priority Data
Jul. 21, 2010 (JP) 2010-163917

(51) Int. Cl. G11C 16/12; G11C 16/14; G11C 16/04; G11C 16/34

(52) U.S. Cl. 365/185.19

(57) ABSTRACT

In one embodiment, a nonvolatile semiconductor storage device includes a plurality of memory cells, and a setting part in which a setting value for prescribing a relation between a program voltage to be applied to the memory cells and a loop number of application processes of the program voltage is set to change the program voltage according to the loop number. The device further includes a voltage controller configured to program data into the memory cells by applying the program voltage depending on the loop number to the memory cells, using the setting value. The device further includes a counter configured to count a maximum value or an average value of final loop numbers in the memory cells, where the final loop numbers are loop numbers in the respective memory cells at time when data programming is completed. The device further includes a setting change part configured to, in response to a change of the counted maximum value or average value from a predetermined maximum value or average value, perform a setting process for canceling the change of the maximum value or average value.

### CROSS REFERENCE TO RELATED APPLICATION

This application is based upon and claims the benefit of priority from the prior Japanese Patent Application No. 2010-163917, filed on Jul. 21, 2010, the entire contents of which are incorporated herein by reference.

### FIELD

Embodiments described herein relates to a nonvolatile semiconductor storage device, for example, to a nonvolatile memory where electrons or holes pass through a tunnel insulator of a memory cell at the time of programming and erasing.

### BACKGROUND

In a conventional nonvolatile memory, especially in a NAND memory having a gate structure including stacked polysilicon layers, electrons are injected from a substrate into a floating gate via a tunnel insulator by an FN (Fowler Nordheim) tunnel current at the time of programming. Therefore, electrons are trapped by the tunnel insulator (electron trap), resulting in characteristics degradation of the tunnel insulator.

On the other hand, at the time of erasing, electrons are drawn from the floating gate into the substrate via the tunnel insulator by the FN tunnel current. Therefore, in the same way as the time of programming, electrons are trapped by the tunnel insulator (electron trap), resulting in characteristics degradation of the tunnel insulator.

It is facilitated to program data into a memory cell by these electron traps, and it becomes a cause of excessive programming of data. On the other hand, it is made hard to erase data from the memory cell, resulting in a prolonged erasing time of data.

In some cases, holes are used instead of electrons as carriers used for storing data in the memory cell. If the carriers are holes, holes are trapped in the tunnel insulator at the time of data programming and data erasing (hole trap).

### BRIEF DESCRIPTION OF THE DRAWINGS

FIG. 1 is a circuit diagram showing a configuration of a nonvolatile semiconductor storage device of a first embodiment;

FIG. 2 is a side sectional view showing how data is programmed into a memory cell;

FIG. 3 is a side sectional view showing how data is erased from the memory cell;

FIG. 4 is a diagram illustrating electron traps at the time of programming;

FIG. 5 is a diagram illustrating hole traps at the time of programming, and narrowing caused by the hole traps;

FIG. 6 is a flow chart for schematically explaining the operation of the semiconductor storage device of the first embodiment at the time of programming;

FIG. 7 is a graph showing relations between a loop number and a program voltage in the first embodiment (at the fresh time);

FIG. 8 is a graph showing threshold distribution in a case where a program verification NG has occurred;

FIG. 9 is a graph showing threshold distribution in a case where over programming has occurred;

FIG. 10 is a graph obtained by plotting a shift of a maximum value of final loop numbers in the first embodiment;

FIG. 11 is a flow chart for explaining the operation of the semiconductor storage device of the first embodiment at the time of programming in detail;

FIG. 12 is a graph showing relations between the loop number and the program voltage after changing the increment of the program voltage;

FIG. 13 is a graph showing relations between the loop number and the program voltage after changing the initial value of the program voltage;

FIG. 14 is a diagram illustrating hole traps at the time of erasing, and narrowing caused by the hole traps;

FIG. 15 is a flow chart for schematically explaining the operation of the semiconductor storage device of a third embodiment at the time of erasing;

FIG. 16 is a graph showing relations between a loop number and an erasure voltage in the third embodiment (at the fresh time);

FIG. 17 is a graph showing threshold distribution in a case where an erasure verification NG has occurred;

FIG. 18 is a graph obtained by plotting a shift of a maximum value of final loop numbers in the third embodiment;

FIG. 19 is a flow chart for explaining the operation of the semiconductor storage device of the third embodiment at the time of erasing in detail;

FIG. 20 is a graph showing relations between the loop number and the erasure voltage after changing the increment of the erasure voltage; and

FIG. 21 is a graph showing relations between the loop number and the erasure voltage after changing the initial value of the erasure voltage.

### DETAILED DESCRIPTION

Embodiments will now be explained with reference to the accompanying drawings.

An embodiment described herein is, for example, a nonvolatile semiconductor storage device including a plurality of memory cells, and a setting part in which a setting value for prescribing a relation between a program voltage to be applied to the memory cells and a loop number of application processes of the program voltage is set to change the program voltage according to the loop number. The device further includes a voltage controller configured to program data into the memory cells by applying the program voltage depending on the loop number to the memory cells, using the setting value. The device further includes a counter configured to count a maximum value or an average value of final loop numbers in the memory cells, where the final loop numbers are loop numbers in the respective memory cells at time when data programming is completed. The device further includes a setting change part configured to, in response to a change of the counted maximum value or average value from a predetermined maximum value or average value, perform a setting process for canceling the change of the maximum value or average value.

Another embodiment described herein is, for example, a nonvolatile semiconductor storage device including a plurality of memory cells, and a setting part in which a setting value for prescribing a relation between an erasure voltage to be applied to the memory cells and a loop number of application processes of the erasure voltage is set to change the erasure voltage according to the loop number. The device further includes a voltage controller configured to erase data from the memory cells by applying the erasure voltage depending on the loop number to the memory cells, using the setting value. The device further includes a counter configured to count a maximum value or an average value of final loop numbers in the memory cells, where the final loop numbers are loop numbers in the respective memory cells at time when data erasure is completed. The device further includes a setting change part configured to, in response to a change of the counted maximum value or average value from a predetermined maximum value or average value, perform a setting process for canceling the change of the maximum value or average value.

### First Embodiment

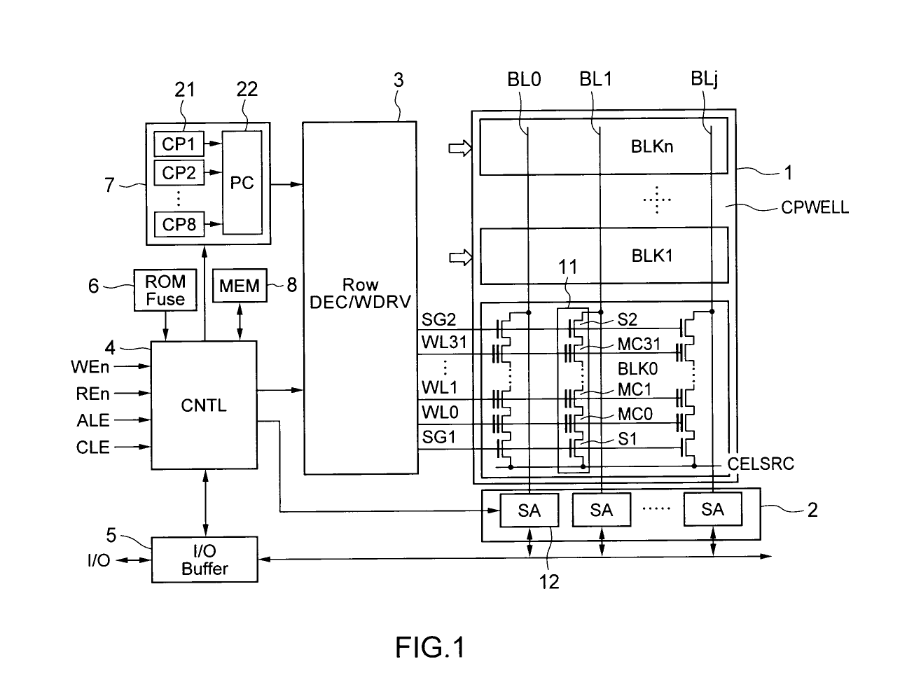

FIG. 1 is a circuit diagram showing a configuration of a nonvolatile semiconductor storage device of a first embodiment. The nonvolatile semiconductor storage device of FIG. 1 is a NAND flash memory.

The nonvolatile semiconductor storage device of FIG. 1 includes a memory cell array 1, a sense amplifier circuit 2, a row decoder 3, a controller 4, an input/output buffer 5, a ROM fuse 6, a voltage generator 7, and a data memory 8.

The memory cell array 1 is formed by arranging NAND cell units 11 in a matrix form. Each NAND cell unit 11 is formed of a plurality of memory cells MC (MC0 to MC31) connected in series, and selection gate transistors S1 and S2 connected to both ends of the memory cells MC.

As well known, each memory cell MC has a floating gate formed on a substrate via a gate insulator (tunnel insulator), and a control gate is formed on the floating gate via an inter-gate insulator. The floating gate functions as a charge storage layer of each memory cell MC. Furthermore, the control gate is connected to one of word lines which will be described later. The substrate is, for example, a silicon substrate, and the tunnel insulator is, for example, a silicon oxide layer.

In this way, each memory cell MC in the present embodiment has the charge storage layer of floating type. Alternatively, however, the memory cell may have a charge storage layer of trap type. Examples of the charge storage layer of floating type include a polysilicon layer and a metal layer. An example of the charge storage layer of trap type includes a silicon nitride layer.

In the NAND cell unit 11, the selection gate transistor S1 has a source connected to a common source line CELSRC, and the selection gate transistor S2 has a drain connected to the corresponding bit line BL (BL0 to BLj).

Control gates of the memory cells MC in the NAND cell unit 11 are connected to different word lines WL (WL0 to WL31), respectively. In addition, gates of the selection gate transistors S1 and S2 are connected respectively to selection gate lines SG1 and SG2 which are disposed in parallel to the word lines WL. A set of a plurality of memory cells MC sharing one word line WL constitutes one page or two pages. A set of a plurality of NAND cell units 11 which share the word lines WL and the selection gate lines SG1 and SG2 constitutes a block BLK which becomes a unit of data erasing.

In the memory cell array 1, a plurality of blocks BLK (BLK0 to BLKn) are arranged in the direction of the bit line BL. The memory cell array 1 including a plurality of blocks BLK is formed in one cell well (CPWELL) of the silicon substrate.

Details of the circuit configuration other than the memory cell array 1 will be described.

The sense amplifier circuit 2 including a plurality of sense amplifiers 12 is connected to the memory cell array 1, and one sense amplifier 12 is connected to each bit line BL in the memory cell array 1. The sense amplifier circuit 2 constitutes a page buffer for sensing read data and retaining programmed data. The sense amplifier circuit 2 includes a column selection gate.

The row decoder (including a word line driver) 3 selects one of the word lines WL and the selection gate lines SG1 and SG2, and drives it.

The input/output buffer 5 transmits and receives data between the sense amplifier circuit 2 and external input/output terminals, and receives command data and address data.

The controller 4 forms a control part for the memory cell array 1. The controller 4 receives an external control signal such as, for example, a program enable signal WEn, a read enable signal REn, an address latch enable signal ALE, and a command latch enable signal CLE, and exercises general control of the memory operation.

Specifically, the controller 4 includes a command interface and an address retention/transfer circuit, and makes a determination whether supplied data is program data or address data. According to a result of this determination, the program data is transferred to the sense amplifier circuit 2, and the address data is transferred to the row decoder 3 and the sense amplifier circuit 2.

The controller 4 further performs sequence control of reading, programming and erasing, and controls applied voltage such as read voltage, program voltage, and erasure voltage based on the external control signal. Details of the control of these applied voltages will be described later.

The voltage generator 7 includes a plurality of (here, eight) boosters 21 and a pulse generator 22. Each booster 21 can be formed of a well known charge pump circuit. The voltage generator 7 switches the number of driven boosters 21, based on a control signal supplied from the controller 4. Each booster 21 further controls the pulse generator 22 and adjusts, for example, the pulse width and pulse height of pulse voltage.

It is possible to previously store the pulse width and pulse height of pulse voltage for the program operation and the erasure operation in, for example, the ROM fuse 6 as voltage setting data. In the same way, it is possible to previously store the number of times of programming and the number of times of erasing as well in, for example, the ROM fuse 6 as voltage setting data. The controller 6 can determine the number of boosters 21 to be driven, based on such voltage setting data.

The data memory 8 is a rewritable nonvolatile memory for storing various data for controlling the nonvolatile semiconductor storage device. For example, setting values for prescribing relations between a loop number and a program/erasure voltage, and setting information for changing setting values are stored in the data memory 8 as described later.

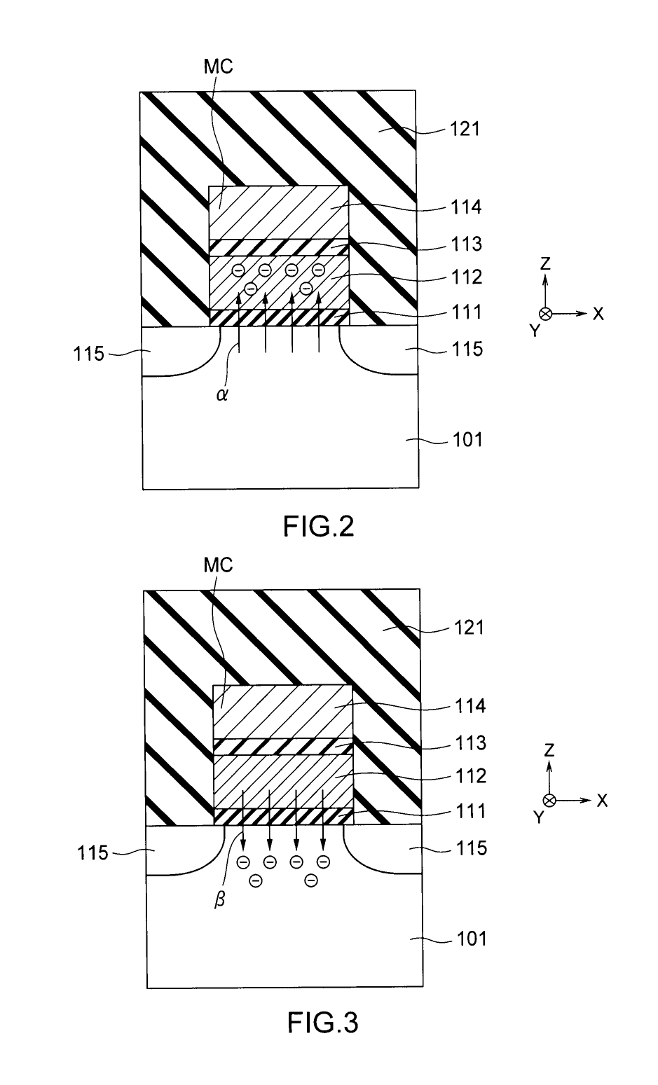

FIG. 2 is a side sectional view showing how data is programmed into a memory cell MC.

As shown in FIG. 2, the memory cell MC includes a floating gate 112 formed on a substrate 101 via a tunnel insulator 111, and includes a control gate 114 formed on the floating gate 112 via an inter-gate insulator 113. FIG. 2 further shows source and drain diffusion layers 115 formed in the substrate 101 to sandwich the memory cell MC, and an inter layer dielectric 121 formed on the substrate 101 to cover the memory cell MC.

FIG. 2 shows an X direction and a Y direction which are parallel to a principal plane of the substrate 101 and are perpendicular to each other, and a Z direction which is perpendicular to the principal plane of the substrate 101. The X direction corresponds to a direction in which the bit lines BL extend, and the Y direction corresponds to a direction in which the word lines WL extend. FIG. 2 is a sectional view obtained by cutting the memory cell MC with a section perpendicular to the Y direction.

When data is programmed into the memory cell MC, electrons are injected from the substrate 101 into the floating gate 112 via the tunnel insulator 111 by an FN tunnel current, as indicated by arrows α. Therefore, electron traps are generated in the tunnel insulator 111, and characteristics degradation of the tunnel insulator 111 is generated.

FIG. 3 is a side sectional view showing how data is erased from the memory cell MC. Similarly to FIG. 2, FIG. 3 is a sectional view obtained by cutting the memory cell MC with a section perpendicular to the Y direction.

When data is erased from the memory cell MC, electrons are drawn out from the floating gate 112 into the substrate 101 via the tunnel insulator 111 by an FN tunnel current, as indicated by arrows β. In the same way as the time of programming, therefore, electron traps are generated in the tunnel insulator 111, and characteristics degradation of the tunnel insulator 111 is generated.

Carriers used in the memory cell MC for storage may be holes instead of electrons.

Hereafter, there is described operation performed at the time of programming in the semiconductor storage device of the present embodiment to cope with problems posed by the electron traps and hole traps.

### (1) Traps and Narrowing

First, traps and narrowing will be described with reference to FIGS. 2 to 5.

As described above, electrons are injected and drawn out by the FN tunnel current at the time of programming and erasing (FIGS. 2 and 3.) If the tunnel insulator 111 is a silicon oxide layer, Si—O bonds which form the silicon oxide layer are cut off by the above FN tunnel current and traps might be generated. Such traps are made apt to be generated by repeating the programming and erasing many times (for example, repeating program/erasure cycles sixty thousand times or more).

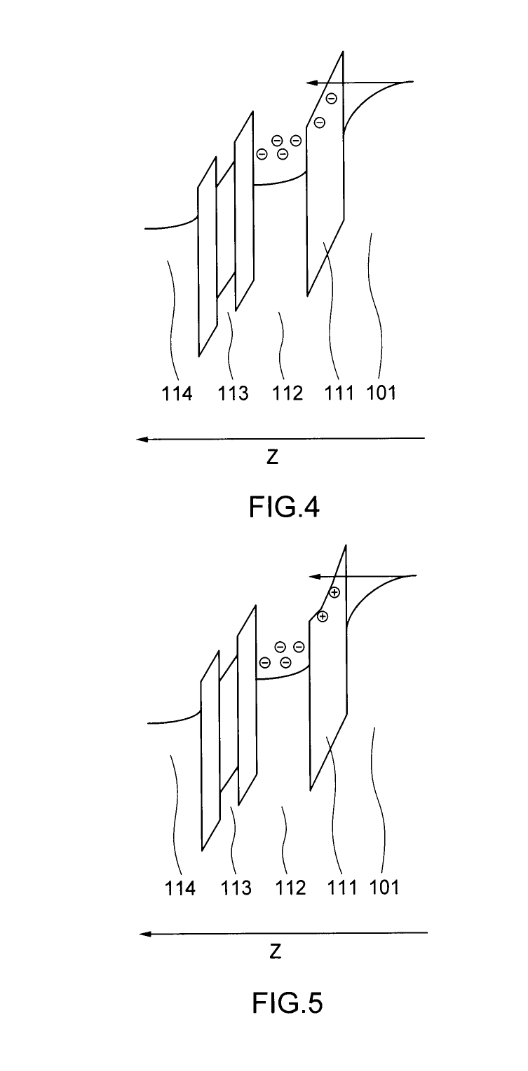

In this way, increasing the number of execution times of the program/erasure cycles in the memory cell MC brings about a state where the traps are apt to be generated. If programming is performed in this state, narrowing of the potential barrier of the tunnel insulator 111 is caused by the traps of electrons or holes in the tunnel insulator 111 (FIGS. 4 and 5). FIG. 4 is a diagram illustrating the electron traps at the time of programming. FIG. 5 is a diagram illustrating the hole traps at the time of programming, and the narrowing caused by the hole traps. The horizontal direction in FIGS. 4 and 5 represents the Z direction, and the vertical direction represents the height direction of the potential.

### (2) Program Processing

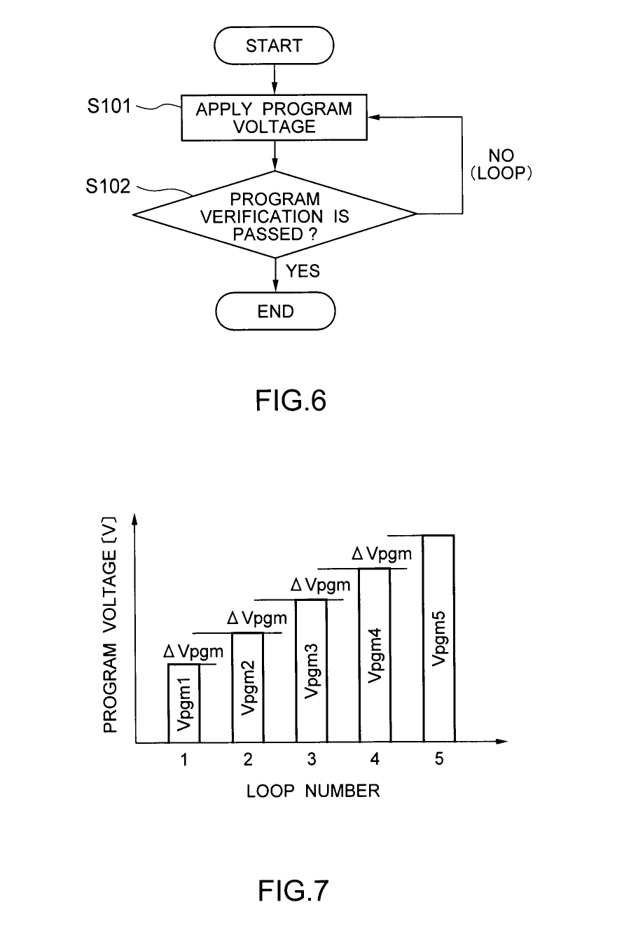

Subsequently, the operation of the semiconductor storage device of the present embodiment at the time of programming will be described with reference to FIGS. 6 to 8.

FIG. 6 is a flow chart for schematically explaining the operation of the semiconductor storage device of the present embodiment at the time of programming. In the present embodiment, application processes of the program voltage to all memory cells MC to be programmed (step S101) and program verifications for determining whether programming has been performed on these memory cells MC (step S102) are performed repeatedly and thereby programming of one cycle is performed.

At this time, the value of the program voltage is set to increase every time the steps of S101 and S102 are repeated as shown in FIG. 7. FIG. 7 is a graph showing relations between the loop number and the program voltage in the present embodiment. The abscissa axis in FIG. 7 represents the loop number in which the steps of S101 and S102 have been repeated, and the ordinate axis represents the program voltage [V].

In FIG. 7, Vpgm1 to Vpgm5 represent program voltages at the time when the loop number is the first to fifth. At the step of S101 in the first to fifth attempt, the program voltages Vpgm1 to Vpgm5 are applied to each memory cell MC. The value of the program voltage Vpgm1 applied at the time of a first loop process corresponds to the initial value of the program voltage with respect to the loop number.

Furthermore, ΔVpgm represents an increment of the program voltage with respect to the loop number. Between a program voltage Vpgm(k) applied in the kth (where k is a positive integer) loop process and a program voltage Vpgm(k+1) applied in the k+1th loop process, the relation Vpgm(k+1)−Vpgm(k)=ΔVpgm holds true. In the present embodiment, ΔVpgm is set to a value which does not depend upon the loop number, i.e., a value which does not depend upon the value of k.

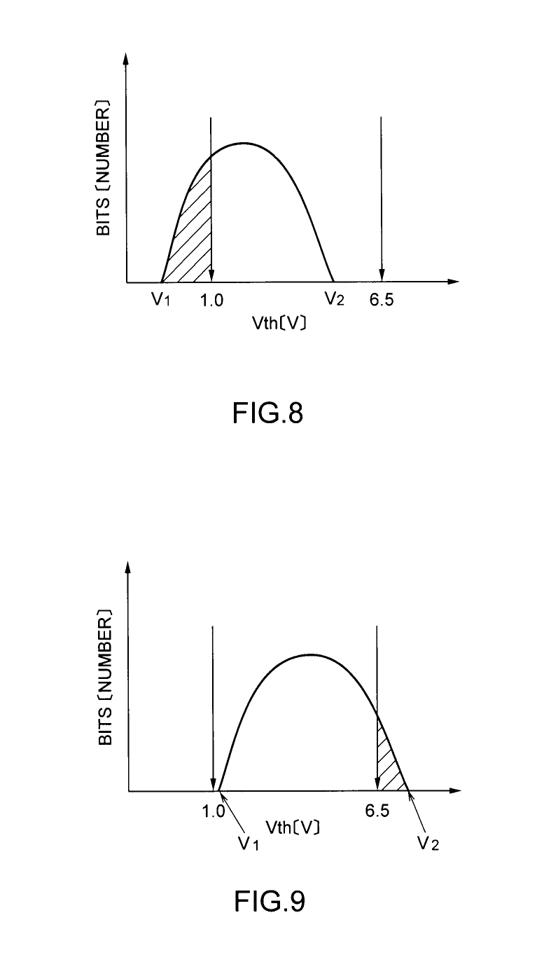

In FIG. 6, the processing at step S102 is performed until the threshold voltage Vth of the all memory cells MC (all bits) to be programmed exceeds the program verification voltage. FIG. 8 is a graph showing threshold distribution in the case where a program verification NG has occurred. The abscissa axis in FIG. 8 represents the threshold voltage Vth [V], and the ordinate axis represents the number of bits. Threshold distribution in the program state is shown in FIG. 8, and a minimum value and a maximum value of the threshold voltage Vth in the threshold distribution are denoted by V₁ and V₂, respectively. In FIG. 8, the verify voltage is 1.0 V and threshold voltage Vth of partial bits becomes lower than the verify voltage. In other words, in FIG. 8, the program verification becomes NG.

Operation of the semiconductor storage device at the time of program operation will be described more specifically with reference to FIG. 6 again.

At the time of programming, the program voltage Vpgm1 (for example, 18 V) is first applied to all bits (all memory cells) to be programmed (S101). Then, it is determined whether the threshold voltages of these bits exceed the program verification voltage (for example, 1.0 V) (S102). If the threshold voltages of all of these bits exceed the program verification voltage, then programming is finished. Operation described heretofore corresponds to the first loop process.

On the other hand, if there are bits for which the threshold voltage does not exceed the program verification voltage (hereafter referred to as remaining bits), a program voltage Vpgm2 obtained by adding an increment ΔVpgm (for example, 1 V) to the program voltage Vpgm1 is applied to these remaining bits (S101). Then, it is determined whether threshold voltages of these remaining bits exceed the program verification voltage (S102). If threshold voltages of all remaining bits exceed the program verification voltage, programming is finished. Operation described heretofore corresponds to second loop process.

In the same way, third and subsequent processes are performed until program verification of all bits to be programmed is passed.

In the above description, the initial value Vpgm1 and the increment ΔVpgm of the program voltage are 18 V and 1 V, respectively. However, different values may be used. In the present embodiment, in order to change the program voltage according to the loop number, the values of the initial value and the increment of the program voltage are stored previously in the data memory (see FIG. 1) as setting values for prescribing the relations between the loop number and the program voltage. The data memory 8 corresponds to an example of a setting part in the disclosure.

At the time of the first loop process, the value of the initial value is used. At the time of second and subsequent loop processes, the program voltage depending on the loop number is generated by using the initial value and the value of increment. Such a program voltage is generated by the voltage generator 7 under the control of the controller 4. In the present embodiment, such a program voltage is applied to all memory cells MC to be programmed, and thereby data are programmed into these memory cells MC (S101). The controller 4 and the voltage generator 7 correspond to an example of a voltage controller in the disclosure.

The values of the initial value and the increment of the program voltage may be stored not in the data memory 8 but in the ROM fuse 6.

(3) Relations between Traps and Narrowing and Program Processing

Subsequently, relations between the traps and narrowing described with reference to FIGS. 4 and 5, and the operation of the semiconductor storage device of the present embodiment at the time of program operation described with reference to FIGS. 6 to 8 will be described.

FIG. 6 shows a flow of processing performed in one program cycle. In this flow, the program voltage is applied to the memory cell to be programmed (S101), and it is determined whether the threshold voltages of these memory cells have exceeded the program verification voltage (S102). And the processing at steps S101 and S102 is repeated until the threshold voltages of all of these memory cells exceed the program verification voltage.

The loop number at the time when data programming of each of these memory cells is completed is referred to as the final loop number. For example, it is supposed that a certain memory cell has passed the program verification in a third loop process, and a different memory cell has passed the program verification in a fifth loop process. In this case, the final loop number of the formerly cited memory cell is three, and the final loop number of the latterly cited memory cell is five.

Further, the loop number at the time when data programming of all memory cells to be programmed is completed is referred to as a maximum value of final loop numbers. For example, if the final loop numbers of six memory cells included in a total of eight memory cells are three, and the final loop numbers of two memory cells are five, the maximum value of the final loop numbers of these memory cells is five. In this case, the processing at steps S101 and S102 shown in FIG. 6 is finished with the loop process at a fifth time. In other words, it is meant that one program cycle is finished by performing loop processes five times.

Here, in the operation at the time of programming at the fresh time (i.e., when the number of times of program/erase is 0) in the semiconductor storage device of the present embodiment, it is supposed that program verifications of all memory cells to be programmed is passed in the loop process of Nth time (N is a positive integer). In other words, it is supposed in the semiconductor storage device of the present embodiment the maximum value of the final loop numbers is N at the fresh time.

If the narrowing described above occurs in this case, then it becomes easier for electrons and holes to pass through the tunnel insulator 111, and consequently the number of times N decreases to, for example, N−2. Since it becomes easier for electrons and holes to pass through the tunnel insulator 111, a possibility that the threshold voltage Vth of partial memory cells will exceed a read voltage (here, 6.5 V) resulting in an over programming failure becomes high as shown in FIG. 9. FIG. 9 is a graph showing threshold distribution in the case where the over programming has occurred.

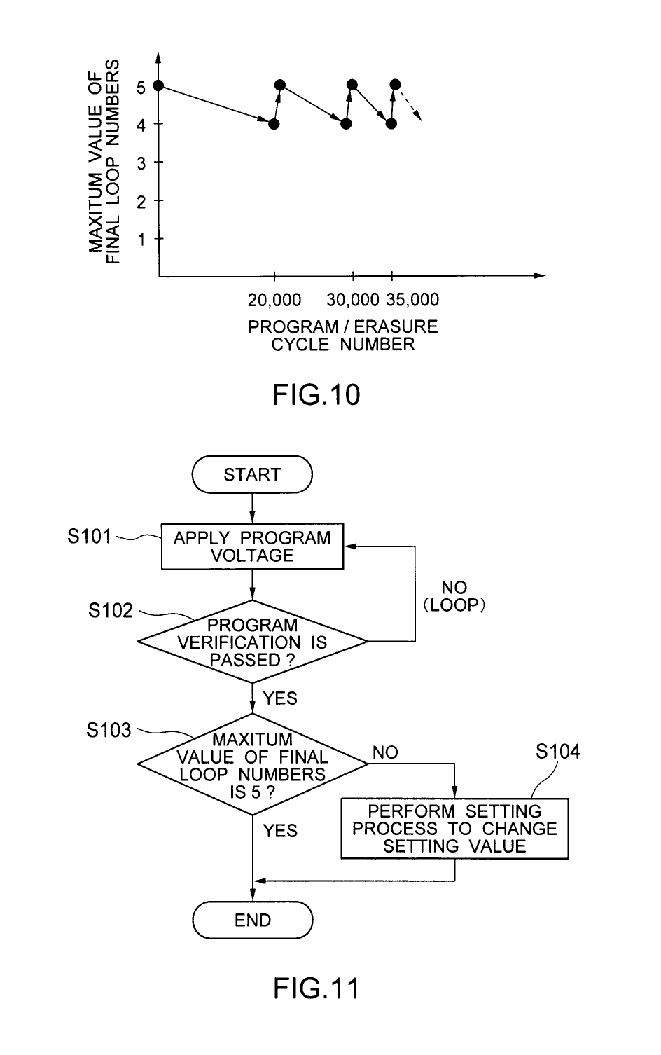

If the maximum value of the final loop numbers has changed from N in a certain program cycle in the present embodiment, then the value of the increment ΔVpgm of the program voltage is changed from the program cycle of the next time to cancel the change. An example of this processing is shown in FIG. 10.

FIG. 10 is a graph obtained by plotting a shift of the maximum value of the final loop numbers in the present embodiment. The abscissa axis in FIG. 10 represents the number of execution times of program/erasure cycles. The ordinate axis in FIG. 10 represents the maximum value of the final loop numbers.

In FIG. 10, in a program cycle in which the number of program/erasure cycles becomes twenty thousand, the maximum value of the final loop numbers decreases from five to four. It is caused by that it is facilitated by the narrowing for electrons and holes to pass through the tunnel insulator 111.

If the maximum value of the final loop numbers has decreased from five to four, the increment of the program voltage is decreased from the program cycle of the next time in the present embodiment. This brings about an effect that it becomes harder for electrons and holes to pass through the tunnel insulator 111. Therefore, it becomes possible to restore the maximum value of the final loop numbers in the program cycle of next time to five by decreasing the increment of the program voltage.

In the present embodiment, therefore, if the maximum value of the final loop numbers has changed from five to four, the increment of the program voltage is decreased from the program cycle of the next time to cancel this change, i.e., to restore the maximum value of the final loop numbers to five. As a result, the effect that it is facilitated by the narrowing for electrons and holes to pass through the tunnel insulator 111 is canceled, and consequently it becomes possible to suppress the generation of over programming. Furthermore, not only at the fresh time but also after many program/erasure cycles, the maximum value of the final loop numbers becomes nearly constant. As a result, the electric field given to the tunnel insulator 111 can be adjusted according to the amount of electron traps (hole traps) in the tunnel insulator 111. In other words, in a state in which programming is made easier, it becomes possible to relax the stress on the tunnel insulator 111 by performing programming with a suitable program voltage with 5 times of looping as compared with the case where programming is performed with a program voltage which is higher than needed and with 4 times of looping. According to the present embodiment, it becomes possible to suppress the degradation of the reliability of the semiconductor storage device by suppressing the generation of over programming and relaxing the stress on the tunnel insulator 111.

In the example shown in FIG. 10, the maximum value of the final loop numbers decreases from five to four in program cycles in which the number of times of program/erasure cycles becomes twenty thousand times, thirty thousand times, and thirty-five thousand times. In the example shown in FIG. 10, therefore, the increment of the program voltage is decreased from the next program cycle. As a result, the maximum value of the final loop numbers is held at a definite value (five).

In the present embodiment, the increment of the program voltage is decreased by, for example, 0.1 V every time the maximum value of the final loop numbers decreases. In this case, in the example shown in FIG. 10, the increment of the program voltage after twenty thousand, thirty thousand, and thirty-five thousand cycles becomes 0.9V, 0.8 V, and 0.7 V, respectively. However, the decrease amount of the increment of the program voltage may be set equal to a value other than 0.1 V.

Hereafter, the operation of the semiconductor storage device of the present embodiment at the time of programming, including such increment change process will be described in detail.

### (4) Details of Program Processing

FIG. 11 is a flow chart for explaining the operation of the semiconductor storage device of the present embodiment at the time of programming in detail. In FIG. 11, steps S103 and S104 are shown in addition to the steps S101 and S102 shown in FIG. 6.

At the time of programming, the program voltage is applied to memory cells to be programmed (S101), and it is determined whether threshold voltages of these memory cells exceed the program verification voltage (S102). The processing at steps S101 and S102 is repeated until the threshold voltages of all of these memory cells exceed the program verification voltage. In the flow shown in FIG. 11, it is supposed that the initial value Vpgm1 of the program voltage is 18 V, the increment ΔVpgm of the program voltage is 1 V, and the maximum value of the final loop numbers is five.

In the semiconductor storage device of the present embodiment, if the number of execution times of the program/erasure cycles increases, then the narrowing described above occurs, and it becomes easy to program data into memory cells. If the initial value and the increment of the program voltage are retained as they are at the fresh time, then the maximum value of the final loop numbers decreases, for example, it decreases to three after execution of sixty thousand cycles.

In the flow shown in FIG. 11, if the program verifications of all memory cells to be programmed are passed and the loop processing at steps S101 and S102 is finished, then it is determined whether the maximum value of the final loop numbers coincides with a predetermined maximum value (the maximum value at the fresh time) (S103). In other words, it is determined whether the maximum value of the final loop numbers is five. If the maximum value of the final loop numbers is five, then the programming is finished.

On the other hand, if the maximum value of the final loop numbers is less than five, a setting process for decreasing the increment of the program voltage from the programming at the next time is performed to restore the maximum value of the final loop numbers to five (S104). In other words, setting for decreasing the increment of the program voltage is set in a predetermined setting place to decrease the increment from the next program cycle. The programming is finished after the execution of the processing at step S104.

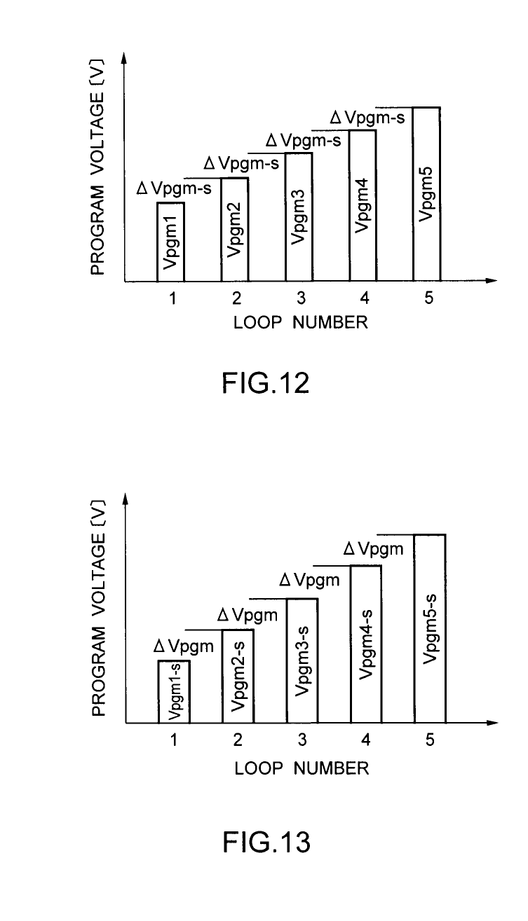

FIG. 12 is a graph showing relations between the loop number and the program voltage after changing the increment of the program voltage. The initial value Vpgm1 of the program voltage shown in FIG. 12 assumes the same value as the initial value Vpgm1 shown in FIG. 7. It should be noted that an increment ΔVpgm-s of the program voltage shown in FIG. 12 is smaller than the increment ΔVpgm shown in FIG. 7 (ΔVpgm-s<ΔVpgm).

The flow chart shown in FIG. 11 will be described in more detail.

When executing the processing shown in FIG. 11 in the present embodiment, the controller 4 (see FIG. 1) counts the maximum value of the final loop numbers, and stores its counted value into the data memory 8. This counted value is used in the processing at step S103 to determine whether the maximum value of the final loop numbers has changed from the maximum value at the fresh time. The function of counting the maximum value of the final loop numbers in the controller 4 corresponds to an example of the counter in the disclosure. The maximum value (i.e., a numerical value of 5) of the final loop numbers at the fresh time to be compared with the counted value at step S103 may be stored in the data memory 8, or may be stored in the ROM fuse 6.

Furthermore, the controller 4 performs a setting process for decreasing the increment of the program voltage when performing programming next time. The function of performing the setting process in the controller 4 corresponds to an example of the setting change part in the disclosure.

An example of the setting place in the processing at step S104 is the data memory 8 (see FIG. 1). An example of the setting process is to set a value of a new increment (for example, 0.9 V), or to set a decrease amount of the increment (for example, 0.1 V) into the data memory 8. Or processing for setting an instruction into the data memory 8 for decreasing the value of the increment may be performed. Or processing for setting the counted value of the maximum value of the final loop numbers may be performed. In the formerly cited case, the controller 4 changes the increment according to the instruction when performing programming next time. In the latterly cited case, the controller 4 recognizes that the maximum value of the final loop numbers has decreased based on the counted value, and changes the increment.

In the present embodiment, the average value of the final loop numbers may be counted instead of counting the maximum value of the final loop numbers in all memory cells to be programmed. For example, if the final loop numbers in four memory cells included in eight memory cells are three, and the final loop numbers in the remaining four memory cells are five, then the average value of the final loop numbers in the memory cells is four. In this case, the average value of the final loop number is used in the processing at steps S103 and S104 instead of the maximum value of the final loop numbers. A value below a decimal point in the average value of the final loop numbers is processed by some threshold processing such as, for example, rounding. If the rounding is adopted, the processing at step S104 corresponds to processing for determining whether the average value of the final loop numbers is within a range of 4.5 to 5.5.

Hereafter, effects of the semiconductor storage device of the present embodiment will be described.

As described above, in the present embodiment, if the maximum value or the average value of the final loop numbers has changed from the predetermined maximum value or average value at the time of programming, the setting value of the program voltage is changed to cancel the change. Specifically, the increment of the program voltage is decreased.

In the present embodiment, therefore, the effect that it is facilitated for electrons or holes to pass through the tunnel insulator 111 by the narrowing is canceled, and consequently it becomes possible to suppress the generation of the over programming. Furthermore, the maximum value or average value of the final loop numbers becomes constant not only at the fresh time but also after many program/erasure cycles. In the consequential state in which programming is facilitated, it becomes possible to relax the stress on the tunnel insulator 111 by performing programming with a suitable program voltage and with a constant loop number, as compared with the case where programming is performed with a voltage which is higher than needed and with a smaller loop number.

According to the present embodiment, it becomes possible to suppress the degradation of the reliability of the semiconductor storage device by suppressing the generation of the over programming and relaxing the stress on the tunnel insulator 111.

Furthermore, the data memory 8 capable of storing the setting for decreasing the increment of the program voltage is provided in the semiconductor storage device of the present embodiment. If the maximum value or average value of the final loop numbers has changed, therefore, it becomes possible in the present embodiment to decrease the increment of the program voltage from the program cycle of next time by previously storing setting for decreasing the increment in the data memory 8. The data memory 8 is used to store, for example, the setting and the counted value of the maximum value or the average value of the final loop numbers.

Hereafter, second to fourth embodiments of the disclosure will be described. Since these embodiments are modifications of the first embodiment, these embodiments will be described laying stress on differences from the first embodiment.

### Second Embodiment

In a second embodiment, program processing is performed according to the flow shown in FIG. 11 in the same way as the first embodiment. However, in the present embodiment, if the maximum value or average value of the final loop numbers has changed from the maximum values or average value at the fresh time, the initial value Vpgm1 of the program voltage is decreased to cancel the change (S104).

In the present embodiment, therefore, it becomes possible to cancel the effect that it is facilitated by the narrowing for electrons and holes to pass through the tunnel insulator 111, and possible to make the maximum value or average value of the final loop numbers constant, in the same way as the first embodiment.

FIG. 13 is a graph showing relations between the loop number and the program voltage after changing the initial value of the program voltage. It should be noted that the increment ΔVpgm of the program voltage shown in FIG. 13 is the same value as the increment ΔVpgm shown in FIG. 6, and the initial value Vpgm1-s of the program voltage shown in FIG. 13 is less than the initial value Vpgm1 shown in FIG. 6 (Vpgm1-s<Vpgm1).

In the present embodiment, the initial value of the program voltage is decreased by, for example, 0.5 V every time the maximum value of the final loop numbers decreases. In this case, the initial value of the program voltage after twenty thousand, thirty thousand and thirty-five thousand cycles become respectively 17.5 V, 17.0 V and 16.5 V in the example shown in FIG. 10. However, the decrease amount of the initial value of the program voltage may be set equal to a value other than 0.5 V.

In the present embodiment, if the maximum value or average value of the final loop numbers has changed from the predetermined maximum value or average value at the time of programming, the initial value of the program voltage is decreased to cancel this change.

In the present embodiment, therefore, the effect that it is facilitated for electrons or holes to pass through the tunnel insulator 111 by the narrowing is canceled, and consequently it becomes possible to suppress the generation of the over programming, in the same way as the first embodiment. Furthermore, in the present embodiment, the maximum value or average value of the final loop numbers becomes constant not only at the fresh time but also after many program/erasure cycles, in the same way as the first embodiment. In the consequential state in which programming is facilitated, it becomes possible to relax the stress on the tunnel insulator 111 by performing programming with a suitable program voltage and with a constant loop number, as compared with the case where the programming is performed with a voltage which is higher than needed and with a smaller loop number. Furthermore, the programming is performed with a low program voltage from the program voltage of the first time by lowering the initial value of the program voltage. As a result, it becomes possible to further relax the stress on the tunnel insulator 111.

According to the present embodiment, it becomes possible to suppress the degradation of the reliability of the semiconductor storage device by suppressing the generation of the over programming and relaxing the stress on the tunnel insulator 111, in the same way as the first embodiment.

As a modification of the first and second embodiments, an embodiment which is responsive to a change of the maximum value or average value of the final loop numbers to change both the initial value and increment of the program voltage are also conceivable. According to the modification as well, effects similar to those of the first and second embodiments can be obtained.

### Third Embodiment

In third and fourth embodiments, the operation of the semiconductor storage device of FIG. 1 at the time of erasing to cope with problems caused by electron traps and hole traps will be described.

### (1) Traps and Narrowing

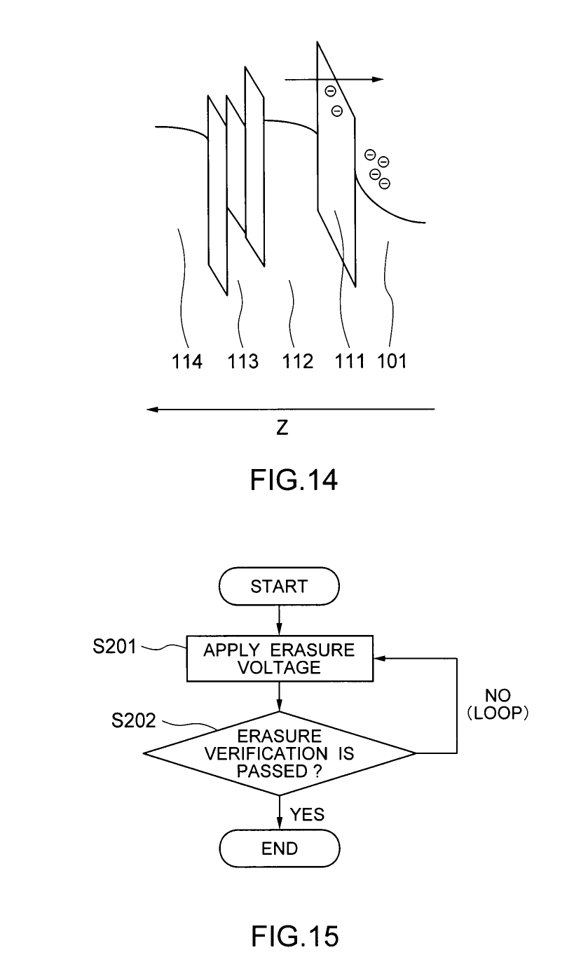

As described above, increasing the number of execution times of the program/erasure cycles in the memory cell MC (FIGS. 2 and 3) brings about a state in which traps are apt to occur. If erasing is performed in this state, narrowing of the potential barrier of the tunnel insulator 111 is caused by traps of electrons or holes in the tunnel insulator 111 (FIG. 14). FIG. 14 is a diagram illustrating hole traps at the time of erasing, and the narrowing caused by the hole traps.

### (2) Erase Processing

Subsequently, the operation of the semiconductor storage device of the third embodiment at the time of erasing will be described with reference to FIGS. 15 to 17.

FIG. 15 is a flow chart for schematically explaining the operation of the semiconductor storage device of the present embodiment at the time of erasing. In the present embodiment, application processes of the program voltage to all memory cells MC to be erased (step S201), and erase verifications for determining whether data has been erased from these memory cells MC (step S202) are performed repeatedly, and thereby erasing of one cycle is performed.

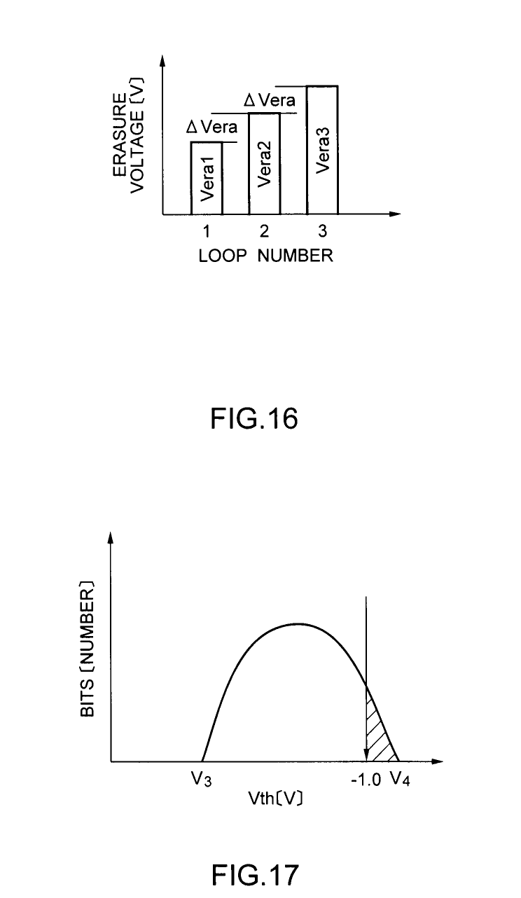

At this time, the value of the erasure voltage is set to increase every time the steps of S201 and S202 are repeated as shown in FIG. 16. FIG. 16 is a graph showing relations between the loop number and the erasure voltage in the present embodiment.

In FIG. 16, Vera1 to Vera3 represent erasure voltages at the time when the loop number is the first to third. The value of the erasure voltage Vera1 corresponds to the initial value of the erasure voltage with respect to the loop number. Furthermore, ΔVera represents the increment of erasure voltage with respect to the loop number. In the present embodiment, ΔVera is set to a value which does not depend upon the loop number.

In FIG. 15, the processing at step S202 is performed until the threshold voltage Vth of the all memory cells MC (all bits) to be erased become lower than the erasure verification voltage (FIG. 17). FIG. 17 is a graph showing threshold distribution in the case where an erasure verification NG has occurred. Threshold distribution in the erase state is shown in FIG. 17, and a minimum value and a maximum value of the threshold voltage Vth in the threshold distribution are denoted by V₃ and V₄, respectively. In FIG. 17, the verify voltage is −1.0 V and threshold voltage of partial bits becomes higher than the verify voltage. In other words, in FIG. 17, the erasure verification becomes NG.

Operation of the semiconductor storage device at the time of erasure operation will be described more specifically with reference to FIG. 15 again.

At the time of erasing, the erasure voltage Vera1 (for example, 15 V) is first applied to all bits (all memory cells) to be erased (S201). Then, it is determined whether the threshold voltages of these bits are lower than the erasure verification voltage (for example, −1.0 V) (S202). If the threshold voltages of all of these bits are lower than the erasure verification voltage, then erasing is finished. Operation described heretofore corresponds to the first loop processes.

On the other hand, if there are bits (hereafter referred to as remaining bits) for which the threshold voltage does not exceed the erasure verification voltage, an erasure voltage Vera1 obtained by adding the increment ΔVera (for example, 1 V) to the erasure voltage Vera2 is applied to the all bits again (S201). Then, it is determined whether the threshold voltages of these bits are lower than the erasure verification voltage (S202). If the threshold voltages of all of these bits are lower than the erasure verification voltage, then erasing is finished. Operation described heretofore corresponds to the second loop process.

In the same way, third and subsequent processing is performed until erase verification of all bits to be erased is passed.

In the above description, the initial value Vera1 and the increment ΔVera of the erasure voltage are 15 V and 1 V, respectively. However, different values may be used. In the present embodiment, in order to change the erasure voltage according to the loop number, the values of the initial value and the increment of the erasure voltage are stored previously in the data memory (see FIG. 1) as setting values for prescribing the relations between the loop number and the erasure voltage. The data memory 8 corresponds to an example of a setting part in the disclosure.

At the time of the first loop process, the value of the initial value is used. At the time of second and subsequent loop processes, the erasure voltage depending on the loop number is generated by using the initial value and the value of increment. Such an erasure voltage is generated by the voltage generator 7 under the control of the controller 4. In the present embodiment, such an erasure voltage is applied to all memory cells MC which are erasing objects, and thereby data are erased from these memory cells MC (S201). The controller 4 and the voltage generator 7 correspond to an example of a voltage controller in the disclosure.

The values of the initial value and the increment of the erasure voltage may be stored not in the data memory 8 but in the ROM fuse 6.

(3) Relations between Traps and Narrowing and Erase Processing

Relations between the trap and the narrowing described with reference to FIG. 14, and the operation of the semiconductor storage device of the present embodiment at the time of erasure operation described with reference to FIGS. 15 to 17 will be described.

In the present embodiment, the loop number at the time when data erasing of each of memory cells to be erased is completed is referred to as the final loop number, in the same way as the first and second embodiments. In addition, the loop number at the time when data erasing of all memory cells to be erased is completed is referred to as a maximum value of the final loop numbers, in the same way as the first and second embodiments.

In the semiconductor storage device of the present embodiment at the fresh time, it is supposed that erase verifications of all memory cells to be erased are passed in the loop process of Mth time (M is a positive integer). In other words, it is supposed in the semiconductor storage device of the present embodiment the maximum value of the final loop numbers is M at the fresh time.

If the narrowing described above occurs in this case, then it becomes harder for electrons and holes to pass through the tunnel insulator 111 conversely to the time of programming (depending upon the position where electrons or holes are trapped in the tunnel insulator 111). Consequently, the number of times M increases to, for example, M+3. As compared with the fresh time, therefore, the erase time becomes long. If the erase time becomes long, there is a possibility that a disadvantage will be caused because of alignment of the erase processing with other processing.

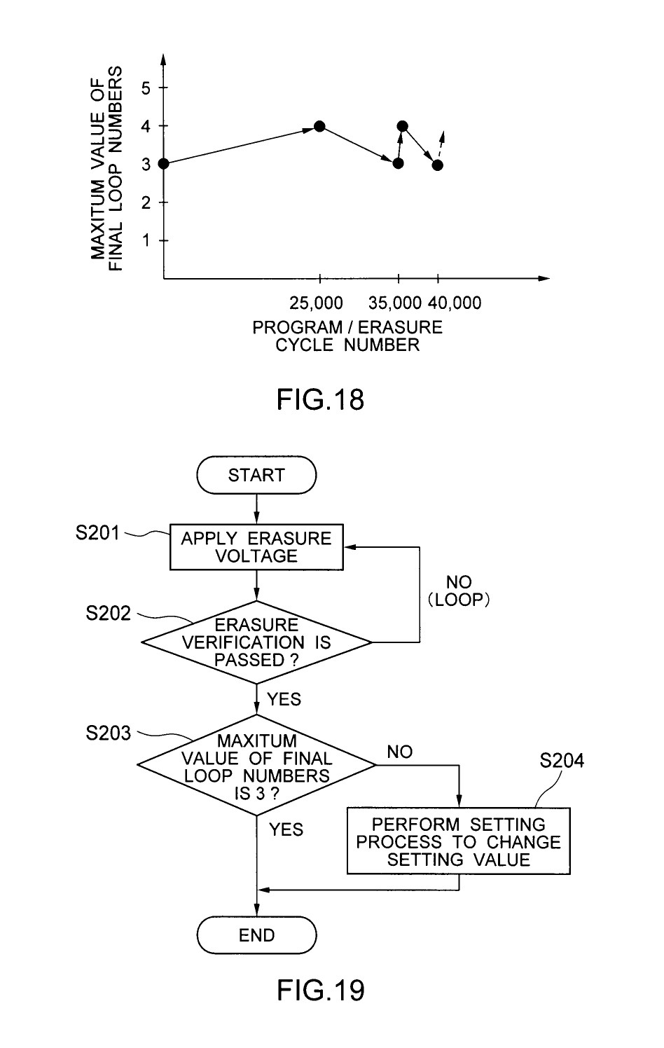

If the maximum value of the final loop numbers has changed from M in a certain erase cycle in the present embodiment, then the value of the increment ΔVera of the erasure voltage is changed from the erase cycle of the next time to cancel the change. An example of this processing is shown in FIG. 18.

FIG. 18 is a graph obtained by plotting a shift of the maximum value of the final loop numbers in the present embodiment. The abscissa axis in FIG. 18 represents the number of execution times of program/erasure cycles. The ordinate axis in FIG. 18 represents the maximum value of the final loop numbers.

In FIG. 18, in an erase cycle in which the number of program/erasure cycles becomes twenty-five thousand, the maximum value of the final loop numbers increases from three to four. It is caused by that it is made harder by the narrowing for electrons and holes to pass through the tunnel insulator 111.

If the maximum value of the final loop numbers has increased from three to four, the increment of the erasure voltage is increased from the erase cycle of the next time in the present embodiment. This brings about an effect that conversely it becomes easier for electrons and holes to pass through the tunnel insulator 111. Therefore, it becomes possible to restore the maximum value of the final loop numbers in the erase cycle of next time to three by increasing the increment of the erasure voltage.

In the present embodiment, therefore, if the maximum value of the final loop numbers has changed from three to four, the increment of the erasure voltage is increased from the erase cycle of the next time to cancel this change, i.e., to restore the maximum value of the final loop numbers to three. As a result, the effect that it is made harder by the narrowing for electrons and holes to pass through the tunnel insulator 111 is canceled, and not only at the fresh time but also after many program/erasure cycles, the maximum value of the final loop numbers becomes constant. As a result, it becomes possible to suppress the time length extension of the erase time caused by the increase of the maximum value of the final loop numbers. According to the present embodiment, it becomes possible to suppress the degradation of the performance in the semiconductor storage device by suppressing the time length extension of the erase time.

In the example shown in FIG. 18, the maximum value of the final loop numbers increases from three to four in erase cycles in which the number of times of program/erasure cycles becomes twenty-five thousand times, thirty-five thousand times, and forty thousand times. In the example shown in FIG. 10, therefore, the increment of the erasure voltage is increased from the next erase cycle. As a result, the maximum value of the final loop numbers is held at a definite value (three).

In the present embodiment, the increment of the erasure voltage is increased by, for example, 0.5 V every time the maximum value of the final loop numbers increases. In this case, in the example shown in FIG. 18, the increment of the erasure voltage after twenty-five thousand, thirty-five thousand, and forty thousand cycles becomes 1.5 V, 2.0 V and 2.5 V, respectively. However, the increase amount of the increment of the erasure voltage may be set equal to a value other than 0.5 V.

Hereafter, operation of the semiconductor storage device of the present embodiment at the time of erasing, including such increment change processing will be described in detail.

### (4) Details of Erase Processing

FIG. 19 is a flow chart for explaining the operation of the semiconductor storage device of the present embodiment at the time of erasing in detail. In FIG. 19, steps S203 and S204 are shown in addition to the steps S201 and S202 shown in FIG. 15.

At the time of erasing, the erasure voltage is applied to memory cells to be erased (S201), and it is determined whether threshold voltages of these memory cells have become lower than the erasure verification voltage (S202). The processing at steps S201 and S202 is repeated until the threshold voltages of all of these memory cells become lower than the erasure verification voltage. In the flow shown in FIG. 19, it is supposed that the initial value Vera1 of the erasure voltage is 15 V, the increment ΔVera of the erasure voltage is 1 V, and the maximum value of the final loop numbers is three.

In the semiconductor storage device of the present embodiment, if the number of execution times of the program/erasure cycles increases, then the narrowing described above occurs and it becomes hard to erase data from memory cells. If the initial value and the increment of the erasure voltage are retained as they are at the fresh time, then the maximum value of the final loop numbers increases, for example, it becomes six after execution of sixty thousand cycles.

In the flow shown in FIG. 19, if erase verifications of all memory cells to be erased are passed and the loop process at steps S201 and S202 is finished, then it is determined whether the maximum value of the final loop numbers coincides with a predetermined maximum value (the maximum value at the fresh time) (S203). In other words, it is determined whether the maximum value of the final loop numbers is three. If the maximum value of the final loop numbers is three, then the erase processing is finished.

On the other hand, if the maximum value of the final loop numbers is greater than three, a setting process for increasing the increment of the erasure voltage from the next erasing is performed to restore the maximum value of the final loop numbers to three (S204). In other words, setting for increasing the increment of the erasure voltage is set in a predetermined setting place to increase the increment from the next program cycle. The erase processing is finished after the execution of the processing at step S204.

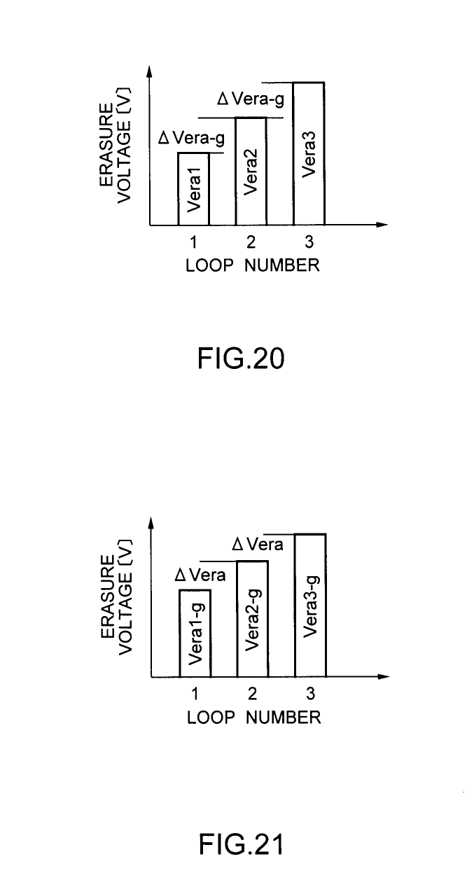

FIG. 20 is a graph showing relations between the loop number and the erasure voltage after changing the increment of the erasure voltage. It should be noted that the initial value Vera1 of the erasure voltage shown in FIG. 20 is the same value as the initial value Vera1 shown in FIG. 16, and the increment ΔVera-g of the erasure voltage shown in FIG. 20 is greater than the increment ΔVera shown in FIG. 16 (ΔVera-g>ΔVera).

The flow chart shown in FIG. 19 will be described in more detail.

When executing the processing shown in FIG. 19 in the present embodiment, the controller 4 (see FIG. 1) counts the maximum value of the final loop numbers, and stores its counted value into the data memory 8, in the same way as the first and second embodiments. This counted value is used in the processing at step S203 to determine whether the maximum value of the final loop numbers has changed from the maximum value at the fresh time. The function of counting the maximum value of the final loop numbers in the controller 4 corresponds to an example of the counter in the disclosure.

Furthermore, the controller 4 performs a setting process for increasing the increment of the erasure voltage when performing erasing next time, in the same way as the first and second embodiments. The function of performing the setting process in the controller 4 corresponds to an example of the setting change part in the disclosure.

In the present embodiment, the average value of the final loop numbers may be counted instead of counting the maximum value of the final loop numbers of all memory cells which to be erased, in the same way as the first and second embodiments. In this case, the average value of the final loop numbers is used instead of the maximum value of the final loop numbers, in the processing at steps S203 and S204.

Hereafter, effects of the semiconductor storage device of the present embodiment will be described.

In the present embodiment, at the time of erasing, if the maximum value or the average value of the final loop numbers has changed from the predetermined maximum value or average value, then the setting value of the erasure voltage is changed to cancel the change as described above. Specifically, the increment of the erasure voltage is increased.

In the present embodiment, therefore, the effect that it is made harder by the narrowing for electrons and holes to pass through the tunnel insulator 111 is canceled, and not only at the fresh time but also after many program/erasure cycles, the maximum value of the final loop numbers becomes constant. As a result, it becomes possible to suppress the time length extension of the erase time caused by the increase of the maximum value of the final loop numbers.

According to the present embodiment, it becomes possible to suppress the degradation of the performance in the semiconductor storage device by suppressing the time length extension of the erase time.

Furthermore, the data memory 8 capable of storing the setting for increasing the increment of the erasure voltage is provided in the semiconductor storage device of the present embodiment. If the maximum value or average value of the final loop number has changed, therefore, it becomes possible in the present embodiment to increase the increment of the erasure voltage from the next erase cycle by previously storing setting for increasing the increment in the data memory 8. The data memory 8 is used to store, for example, the setting and the counted value of the maximum value or the average value of the final loop numbers.

### Fourth Embodiment

In a fourth embodiment, erase processing is performed according to the flow shown in FIG. 19, in the same way as the third embodiment. However, in the present embodiment, if the maximum value or average value of the final loop numbers has changed from the maximum value or average value at the fresh time, the initial value Vera1 of the erasure voltage is increased to cancel the change (S204).

In the present embodiment, therefore, it becomes possible to cancel the effect that it is made harder by the narrowing for electrons and holes to pass through the tunnel insulator 111, and possible to make the maximum value or average value of the final loop numbers constant, in the same way as the third embodiment.

FIG. 21 is a graph showing relations between the loop number and the erasure voltage after changing the initial value of the erasure voltage. It should be noted that the increment ΔVera of the erasure voltage shown in FIG. 21 is the same value as the increment ΔVera shown in FIG. 16, and the initial value Vera1-g of the erasure voltage shown in FIG. 21 is greater than the initial value Vera1 shown in FIG. 16 (Vera1-g>Vera1).

In the present embodiment, the initial value of the erasure voltage is increased by, for example, 1 V every time the maximum value of the final loop numbers increases. In this case, the initial value of the erasure voltage after twenty-five thousand, thirty-five thousand and forty thousand cycles become respectively 16 V, 17 V and 18 V in the example shown in FIG. 10. However, the increase amount of the initial value of the erasure voltage may be set equal to a value other than 1 V.

In the present embodiment, if the maximum value or average value of the final loop numbers has changed from the predetermined maximum value or average value at the time of erasing, then the initial value of the erasure voltage is increased to cancel this change.

In the present embodiment, therefore, the effect that it is made harder by the narrowing for electrons and holes to pass through the tunnel insulator 111 is canceled, and not only at the fresh time but also after many program/erasure cycles, the maximum value of the final loop numbers becomes constant. As a result, it becomes possible to suppress the time length extension of the erase time caused by the increase of the maximum value of the final loop numbers.

According to the present embodiment, it becomes possible to suppress the degradation of the performance in the semiconductor storage device by suppressing the time length extension of the erase time, in the same way as the third embodiment.

As a modification of the third and fourth embodiments, an embodiment which is responsive to a change of the maximum value or average value of the final loop numbers to change both the initial value and increment of the erasure voltage are also conceivable. According to the modification as well, effects similar to those of the third and fourth embodiments can be obtained.

As described above, according to the embodiments described herein, it becomes possible to provide a nonvolatile semiconductor storage device capable of reducing the degradation of device reliability and performance caused by the electron traps and the hole traps in the tunnel insulator.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A nonvolatile semiconductor storage device comprising:
a plurality of memory cells;
a setting part in which a setting value for prescribing a relation between a program voltage to be applied to the memory cells and a loop number of application processes of the program voltage is set to change the program voltage according to the loop number;
a voltage controller configured to program data into the memory cells by applying the program voltage depending on the loop number to the memory cells, using the setting value;
a counter configured to count a maximum value or an average value of final loop numbers in the memory cells, where the final loop numbers are loop numbers in the respective memory cells at time when data programming is completed; and
a setting change part configured to, in response to a change of the counted maximum value or average value from a predetermined maximum value or average value, perform a setting process for canceling the change of the maximum value or average value.

2. The device according to claim 1, wherein
the setting value is an increment of the program voltage with respect to the loop number, and
the setting change part performs the setting process for changing the increment.

3. The device according to claim 2, wherein
a value of the increment set in the setting part, and a new value of the increment to be changed by the setting change part, are independent of the loop number.

4. The device according to claim 1, wherein
the setting value is an initial value of the program voltage with respect to the loop number, and
the setting change part performs the setting process for changing the initial value.

5. The device according to claim 1, wherein
in the setting process, the setting change part sets a value of the setting value after the change, or a change amount from a value of the setting value before the change to a value of the setting value after the change, in a predetermined setting place.

6. The device according to claim 1, wherein
in the setting process, the setting change part sets an instruction for changing the setting value, in a predetermined setting place.

7. The device according to claim 1, wherein
in the setting process, the setting change part sets a counted value of the maximum value or average value by the counter, in a predetermined setting place.

8. The device according to claim 1, wherein
the predetermined maximum value or average value is a maximum value or average value of the final loop numbers at time when the voltage controller programs data into the memory cells when the nonvolatile semiconductor storage device is fresh.

9. The device according to claim 1, wherein
the voltage controller programs data into the memory cells by repeatedly performing the application processes of the program voltage and verification processes of determining whether data is programmed into the memory cells.

10. The device according to claim 9, wherein
the voltage controller repeatedly performs the application processes and the verification processes until threshold voltages of all of the memory cells to be programmed becomes higher than a program verification voltage.

11. A nonvolatile semiconductor storage device comprising:
a plurality of memory cells;
a setting part in which a setting value for prescribing a relation between an erasure voltage to be applied to the memory cells and a loop number of application processes of the erasure voltage is set to change the erasure voltage according to the loop number;
a voltage controller configured to erase data from the memory cells by applying the erasure voltage depending on the loop number to the memory cells, using the setting value;
a counter configured to count a maximum value or an average value of final loop numbers in the memory cells, where the final loop numbers are loop numbers in the respective memory cells at time when data erasure is completed; and
a setting change part configured to, in response to a change of the counted maximum value or average value from a predetermined maximum value or average value, perform a setting process for canceling the change of the maximum value or average value.

12. The device according to claim 11, wherein
the setting value is an increment of the erasure voltage with respect to the loop number, and
the setting change part performs the setting process for changing the increment.

13. The device according to claim 12, wherein
a value of the increment set in the setting part, and a new value of the increment to be changed by the setting change part, are independent of the loop number.

14. The device according to claim 11, wherein
the setting value is an initial value of the erasure voltage with respect to the loop number, and
the setting change part performs the setting process for changing the initial value.

15. The device according to claim 11, wherein
in the setting process, the setting change part sets a value of the setting value after the change, or a change amount from a value of the setting value before the change to a value of the setting value after the change, in a predetermined setting place.

16. The device according to claim 11, wherein
in the setting process, the setting change part sets an instruction for changing the setting value, in a predetermined setting place.

17. The device according to claim 11, wherein
in the setting process, the setting change part sets a counted value of the maximum value or average value by the counter, in a predetermined setting place.

18. The device according to claim 11, wherein
the predetermined maximum value or average value is a maximum value or average value of the final loop numbers at time when the voltage controller erases data from the memory cells when the nonvolatile semiconductor storage device is fresh.

19. The device according to claim 11, wherein
the voltage controller erases data from the memory cells by repeatedly performing the application processes of the erasure voltage and verification processes of determining whether data is erased from the memory cells.

20. The device according to claim 19, wherein
the voltage controller repeatedly performs the application processes and the verification processes until threshold voltages of all of the memory cells to be erased becomes lower than an erasure verification voltage.
